(19) United States
(12) Patent Application Publication
(10) Pub. No.: US 2026/0190272 A1
(43) Pub. Date: Jul. 2, 2026

(54) SERVER

(71) Applicant: Fulian Precision Electronics (Tianjin) Co., LTD., Tianjin (CN)

(72) Inventors: LIANG GAO, Tianjin (CN); XIAO-LI YAN, Tianjin (CN); FANG-XING YANG, Tianjin (CN); YA-NI ZHANG, Tianjin (CN); WEN-TZU CHEN, New Taipei (TW); QING-SONG ZENG, New Taipei (TW); CHEN-HAO SU, New Taipei (TW); XIANG-YU LEI, New Taipei (TW); LI-PING CHEN, New Taipei (TW); HONG-ZHANG LIN, New Taipei (TW)

(21) Appl. No.: 19/217,022

(22) Filed: May 23, 2025

(30) Foreign Application Priority Data
Dec. 28, 2024 (CN) 202411957383.1

(51) Int. Cl. H05K 7/14; H05K 7/20

(52) U.S. Cl. CPC H05K 7/1489; H05K 7/20727

(57) ABSTRACT

A server includes a case with a sidewall and a front opening, a bracket within the case rotatable between a working position and a maintaining position for holding electronic devices, a chassis slidable into or out of the case through the front opening, and a fan on the chassis movable between a lower height and an upper height. When the chassis slides into the case, the fan is at the lower height, and the bracket rotates to the working position, positioning the electronic devices between the fan and the opening for cooling by the fan. When the bracket rotates to the maintaining position, the chassis slides out, and the fan moves to the upper height above the bracket, allowing the fan to slide out for maintenance.

### FIELD

The disclosure herein generally relates to information computing systems, and more particularly relates to a server.

### BACKGROUND

Servers are usually equipped with a fan, and the fan sometimes needs to be removed from the server for maintenance or replacement. However, due to the compact structure of the server, removing the fan requires disassembling the server's case to take out the fan, which is complex and time-consuming.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a server in an embodiment of the present application.

FIG. 2 is a side view of a portion of the server shown in FIG. 1, showing a chassis slid into a case, a bracket in a working position, and a fan at a lower height.

FIG. 3 is a side view of the portion of the server shown in FIG. 2, showing the chassis slid out of the case, the bracket in a maintaining position, and the fan at an upper height.

FIG. 4 is an isometric view of a chassis and a sidewall shown in FIG. 3, showing the bracket in the maintaining position and the fan at the upper height.

FIG. 5 is an enlarged view of area A in FIG. 4.

FIG. 6 is an exploded view of the sidewall, the slide board, and the frame in FIG. 4.

FIG. 7 is an isometric view of the sidewall shown in FIG. 6 from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

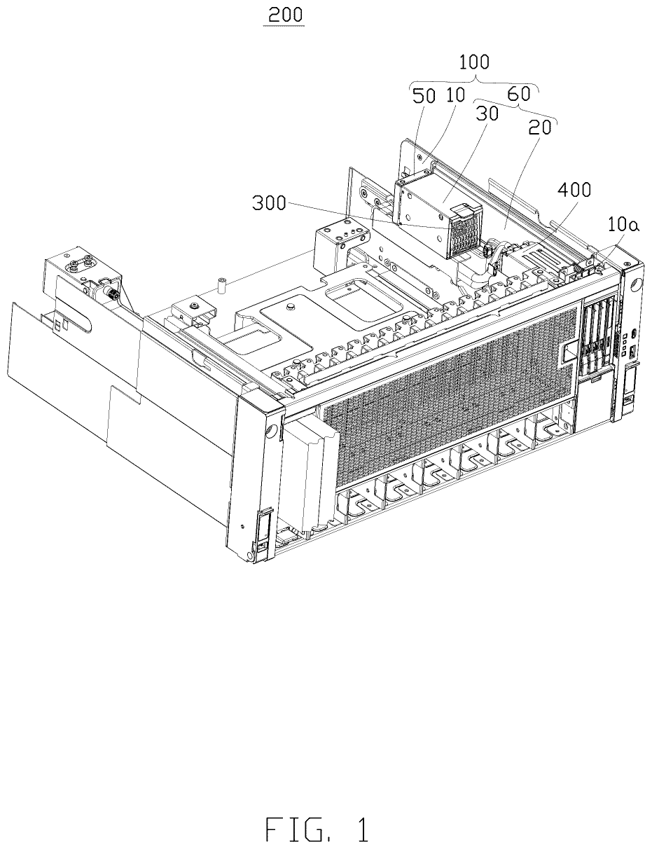

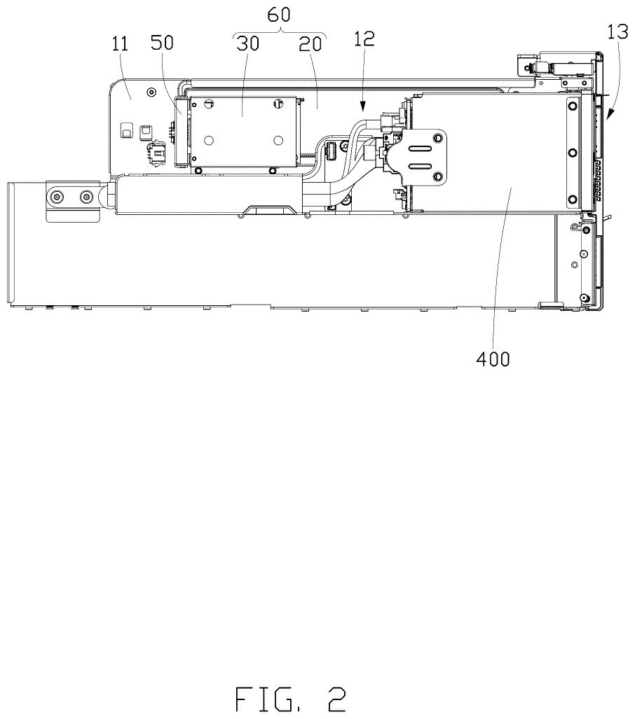

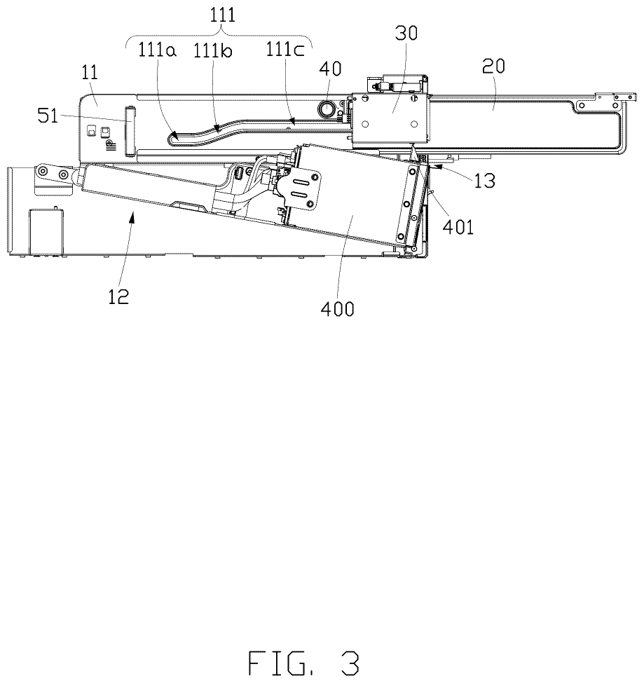

As shown in FIG. 1 to FIG. 3, an embodiment of the present application provides a server 200, and the server 200 includes a case 100 and a fan 300. The case 100 includes a case shell 10. The case 100 contains a bracket 400, which is used to install electronic devise, such as hard disks. The bracket 400 is rotatable between a working position (FIG. 2) and a maintaining position (FIG. 3).

As shown in FIG. 2 to FIG. 7, the server 200 further includes a chassis 60. The chassis 60 includes a slide board 20 and a frame 30. The case shell 10 includes a sidewall 11. The case shell 10 forms an interior space 12 on one side of the sidewall 11. The front side of the case shell 10 is provided with a front opening 13 communicating with the interior space 12. The sidewall 11 is provided with a groove rail 111. The groove rail 111 includes a lower horizontal section 111a, an inclined section 111b, and an upper horizontal section 111c connected in sequence. The lower horizontal section 111a and the upper horizontal section 111c extend horizontally. The upper horizontal section 111c is located obliquely above the lower horizontal section 111a. The inclined section 111b is inclined. The bracket 400 is located within the interior space 12. The inner end of the bracket 400 is rotatably connected to the sidewall 11. The slide board 20 is disposed on the sidewall 11 and is horizontally slidable relative to the sidewall 11. The slide board 20 is capable of sliding out of or into the interior space 12 through the front opening 13. The frame 30 is used to accommodate the fan 300. The frame 30 is disposed at the tail end of the slide board 20 and is vertically movable relative to the slide board 20. The frame 30 is provided with a pin 31. The pin 31 is slidably located in the groove rail 111. For example, the pin 31 is a bearing. When the pin 31 slides in the inclined section 111b, the frame 30 moves vertically relative to the slide board 20. When the pin 31 is in the lower horizontal section 111a, the frame 30 is at a lower height. When the pin 31 is in the upper horizontal section 111c, the frame 30 is at an upper height.

For example, the bracket 400 is rotatable around a shaft at the rear end of the bracket 400, the shaft is perpendicular to the direction of the slide of the chassis relative to the case.

When the fan 300 is installed in the case 100, as shown in FIG. 2, the bracket 400 is in the working position. At this time, the bracket 400 blocks the front opening 13. The slide board 20 is located within the interior space 12. The frame 30 is at the lower height. The fan 300 in the frame 30 is also at the lower height. The fan 300 is located behind the bracket 400. When the fan 300 operates, it blows air toward the bracket 400 to dissipate heat from the bracket 400.

When the fan 300 needs to be removed, as shown from FIG. 2 to FIG. 3, the bracket 400 is first rotated downward from the working position to the maintaining position. The bracket 400 in the maintaining position no longer blocks the front opening 13. Then, the slide board 20 is pulled out of the interior space 12. During the pulling process, the pin 31 slides from the lower horizontal section 111a through the inclined section 111b and into the upper horizontal section 111c. This causes the frame 30 to rise from the lower height to the upper height and simultaneously slide to the front opening 13. This allows personnel to remove the fan 300 from the frame 30 at the front opening 13 or install the fan 300 into the frame 30 at the front opening 13.

When the fan 300 needs to be reinstalled, as shown from FIG. 3 to FIG. 2, the slide board 20 is first pushed into the interior space 12. During the pushing process, the pin 31 slides from the upper horizontal section 111c through the inclined section 111b and into the lower horizontal section 111a. This causes the frame 30 to descend from the upper height to the lower height. Then, the bracket 400 is rotated upward from the maintaining position to the working position. The bracket 400 blocks the front opening 13. At this time, the fan 300 is located behind the bracket 400. When the fan 300 operates, it blows air toward the bracket 400 to dissipate heat. In summary, the case 100 enhances the convenience of installing and removing the fan 300 through the above method. It eliminates the need to disassemble the outer shell of the case 100, making it easier to install and remove the fan 300.

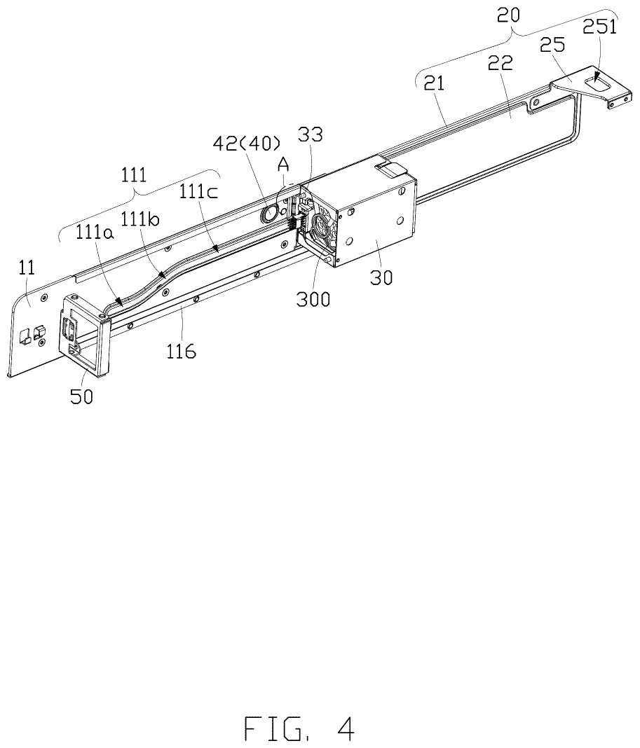

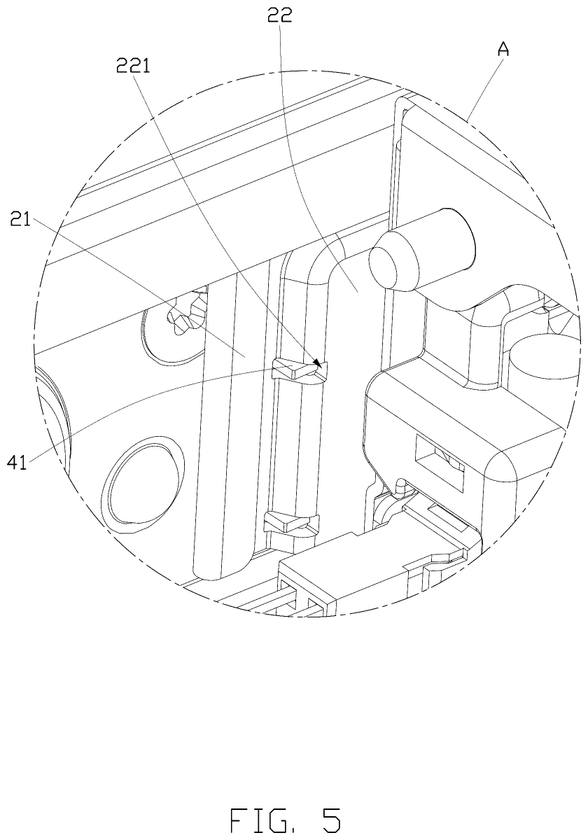

In some embodiments, as shown in FIG. 4 and FIG. 5, the server 200 further includes a spring leaf 40. The spring leaf 40 is disposed on the sidewall 11. The spring leaf 40 is provided with a sheet 41. The sheet 41 is located at the front opening 13. The slide board 20 includes an edge part 21 and a bump part 22. The edge part 21 surrounds the edge of the bump part 22. The bump part 22 protrudes relative to the edge part 21 toward the side away from the sidewall 11. The edge part 21 adheres to the sidewall 11 and is slidable along the sidewall 11. A hollow space 23 is formed between the bump part 22 and the sidewall 11. When the slide board 20 slides, the sheet 41 is located within the hollow space 23, preventing the sheet 41 from interfering with the sliding of the slide board 20. When the slide board 20 slides out of the interior space 12, the sheet 41 abuts against the tail end of the bump part 22, preventing the slide board 20 from continuing to slide outward through the front opening 13. The sheet 41 prevents the slide board 20 from detaching from the sidewall 11.

In some embodiments, the tail end of the bump part 22 is provided with a check slot 221. The check slot 221 is used to accommodate the sheet 41. When the slide board 20 slides out of the interior space 12, the sheet 41 is inserted into the check slot 221, preventing the slide board 20 from continuing to slide outward through the front opening 13. This more stably prevents the slide board 20 from sliding.

In some embodiments, as shown in FIG. 4 to FIG. 6, the spring leaf 40 is elastic. For example, the spring leaf 40 is a resilient sheet. One end of the spring leaf 40 is fixed to the outer surface of the sidewall 11. The other end of the spring leaf 40 is provided with a button 42. The sidewall 11 is provided with a button hole 112. The button 42 is exposed inside the case 100 through the button hole 112. The sheet 41 is located at the middle portion of the spring leaf 40. The sidewall 11 is provided with a slot 113. The sheet 41 passes through the slot 113 and extends into the hollow space 23. When personnel press and push the button 42 outward, the spring leaf 40 deforms, pulling the sheet 41 out of the slot 113. This causes the sheet 41 to leave the hollow space 23, allowing the slide board 20 to be removed from the sidewall 11 or assembled onto the sidewall 11 for maintenance or other operations.

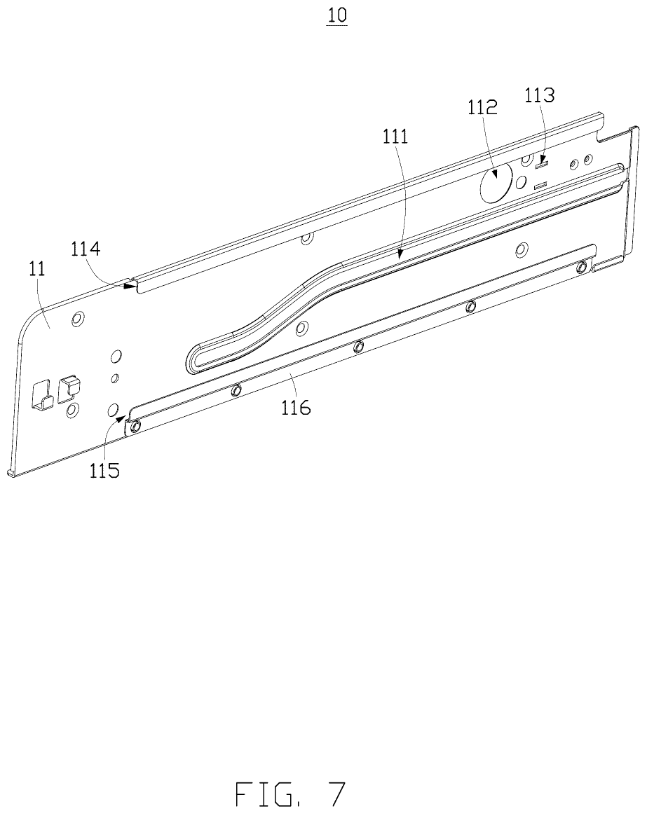

In some embodiments, as shown in FIG. 7, the inner surface of the sidewall 11 is provided with a horizontal upper guiding slot 114 and a lower guiding slot 115. The upper guiding slot 114 is located above the lower guiding slot 115. The top of the edge part 21 is slidably located in the upper guiding slot 114. The bottom of the edge part 21 is slidably located in the lower guiding slot 115. This allows the slide board 20 to slide horizontally relative to the sidewall 11.

In some embodiments, as shown in FIG. 7, the top edge of the sidewall 11 is bent inward to form the upper guiding slot 114. The inner surface of the sidewall 11 is provided with a bent plate 116. The gap between the bent plate 116 and the inner surface of the sidewall 11 forms the lower guiding slot 115, simplifying the structure of the sidewall 11.

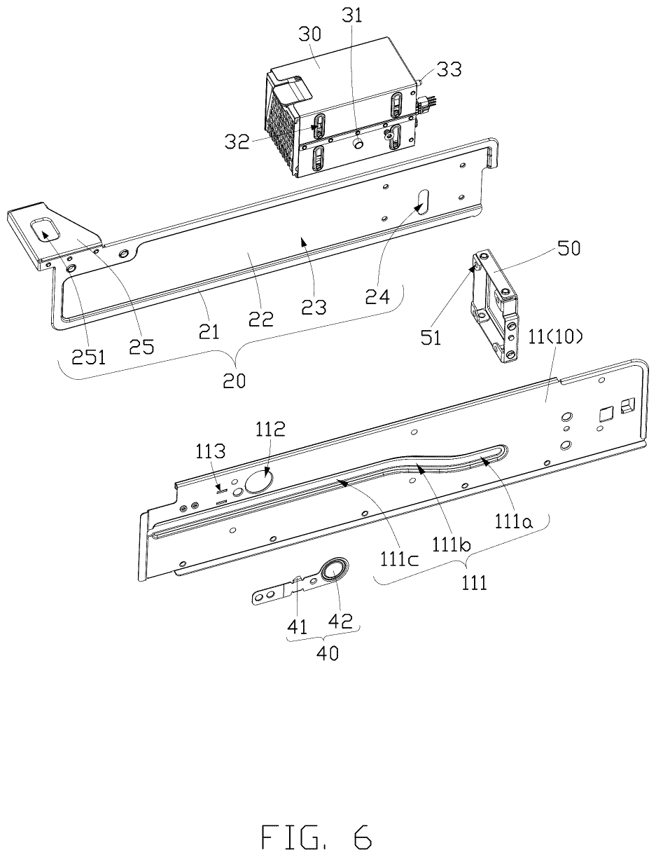

In some embodiments, as shown in FIG. 6, the slide board 20 is provided with a vertical slot 24. The vertical slot 24 extends vertically. The pin 31 passes through the vertical slot 24 and is inserted into the groove rail 111. The pin 31 is slidable in the vertical slot 24. When the pin 31 slides in the inclined section 111b, the pin 31 simultaneously slides vertically in the vertical slot 24. The vertical slot 24 prevents the slide board 20 from interfering with the vertical movement of the frame 30.

In some embodiments, as shown in FIG. 6, the frame 30 is provided with four guiding slots 32. Each guiding slot 32 extends vertically. The four guiding slots 32 are distributed around the pin 31. The slide board 20 is provided with four latches 31. Each latch 31 is fixed relative to the slide board 20. Each latch 31 is inserted into a corresponding guiding slot 32 and is slidable within the guiding slot 32. This allows the frame 30 to slide vertically relative to the slide board 20 stably.

In some embodiments, the sidewall 11 is provided with a positioning rack 50. The positioning rack 50 is located behind the slide board 20. The positioning rack 50 is provided with a positioning hole 51. The rear side of the frame 30 is provided with a positioning pin 33. The positioning hole 51 is aligned with the positioning pin 33. When the slide board 20 slides into the interior space 12, the positioning pin 33 is inserted into the positioning hole 51. The positioning rack 50 positions the frame 30 within the interior space 12, locating the working position of the fan 300.

In some embodiments, as shown in FIG. 1 to FIG. 4, the front side of the slide board 20 is provided with a lock board 25. The top of the lock board 25 is provided with a buckle slot 251. The case shell 10 is provided with a buckle 10a corresponding to the position of the lock board 25. When the slide board 20 slides into the interior space 12, the buckle 10a is inserted into the buckle slot 251, locking the position of the slide board 20 and preventing the slide board 20 from accidentally sliding out of the interior space 12. When the slide board 20 needs to be pulled out, personnel must first press the buckle 10a to unlock the positioning of the slide board 20 relative to the case shell 10 before pulling out the slide board 20.

In some embodiments, as shown in FIG. 1 to FIG. 4, the top of the front end of the bracket 400 is provided with a positioning protrusion 401. When the slide board 20 slides into the interior space 12 and the bracket 400 is in the working position, the positioning protrusion 401 is inserted into the buckle slot 251. The buckle 10a locks the positioning protrusion 401. At this time, the slide board 20 is restricted by the positioning protrusion 401 and cannot slide out of the interior space 12. The bracket 400 is also restricted by the buckle 10a and cannot rotate downward to the maintaining position. This allows the buckle 10a to simultaneously lock the slide board 20 and the bracket 400.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A server comprising:
a case comprising a sidewall and a front opening;
a bracket placed in the case, rotatable between a working position and a maintaining position, and configured for holding electronic devices;
a chassis disposed on the sidewall and slidable into or out of the case through the front opening; and
a fan disposed on the chassis and movable between a lower height and an upper height, wherein when the chassis is slid into the case, the fan is at the lower height, and the bracket is rotatable to the working position wherein the electronic devices are between the fan and the opening, the fan cools the electronic devices;
when the bracket is rotated to the maintaining position, the chassis is slidable out of the case, and the fan moves to the upper height as the chassis slides out of the case, the fan at the upper height is above the bracket in the maintaining position, such that the fan is slidable out of the case for maintenance.

2. The server of claim 1, wherein the sidewall comprises a groove rail, the groove rail comprises a lower horizontal section, an inclined section, and an upper horizontal section connected in sequence, the chassis comprises a slide board and a frame, the fan is positioned in the frame, the frame is disposed on the slide board and is slidable vertically relative to the slide board between the lower height and the upper height, the slide board is disposed on the sidewall and slidable horizontally into or out of the case through the front opening, the frame comprises a pin, the pin is disposed in the groove rail and slidable along the groove rail, when the pin is in the lower horizontal section, the frame and the fan are at the lower height, when the pin is in the upper horizontal section, the frame and the fan are at the upper height, when the slide board slides out of the case, the pin slides from the lower horizontal section through the inclined section into the upper horizontal section, when the pin slides in the inclined section, the frame and the fan move vertically relative to the slide board from the lower height to the upper height.

3. The server of claim 2 further comprises a spring leaf, the spring leaf is disposed on the sidewall, the spring leaf is provided with a sheet, the slide board comprises an edge part and a bump part, the edge part is disposed at the edge of the bump part, the bump part protrudes relative to the edge part toward a side away from the sidewall, the edge part is attached to the sidewall, a hollow space is formed between the bump part and the sidewall, the sheet is located in the hollow space, when the slide board is slid out of the case, the sheet abuts against a tail end of the bump part to stop the slide board from being detached from the sidewall.

4. The server of claim 3, wherein the tail end of the bump part is provided with a check slot, the check slot is configured to accommodate the sheet, when the slide board is slid out of the case and the sheet is inserted into the check slot, the sheet stops the slide board from being detached from the sidewall.

5. The server of claim 3, wherein the slide board is disposed on an inner surface of the sidewall, one end of the spring leaf is fixed to an outer surface of the sidewall, another end of the spring leaf is provided with a button, the sidewall is provided with a button hole, the button is exposed inside the case through the button hole, the sheet is located on the spring leaf, the sidewall is provided with a slot, when the spring leaf is released, the sheet passes through the slot and extends into the hollow space, when the button is pressed from inside to outside of the case, the spring leaf deforms and the sheet moves out of the slot, such that the sheet leaves the hollow space and the slide board is detachable from the sidewall.

6. The server of claim 3, wherein an upper edge of the inner surface of the sidewall forms an upper slide slot, a lower edge of the inner surface of the sidewall forms a lower slide slot, the upper slide slot and the lower slide slot are horizontal, a top of the edge part is slidably positioned in the upper slide slot, a bottom of the edge part is slidably positioned in the lower slide slot, such that the slide board is slidable horizontally relative to the sidewall.

7. The server of claim 6, wherein the upper slide slot is formed by bending the upper edge of the inner surface of the sidewall, the inner surface of the sidewall is provided with a bent plate, a gap between the bent plate and the inner surface of the sidewall forms the lower slide slot.

8. The server of claim 2, wherein the slide board is provided with a vertical slot, the vertical slot extends vertically, the pin passes through the vertical slot and is inserted into the groove rail, the pin is slidable in the vertical slot.

9. The server of claim 2, wherein the frame is provided with four guiding slots, each guiding slot extends vertically, the four guiding slots are distributed around the pin, the slide board is provided with four latches, the four latches are fixed on the slide board, each of the four latches is slidably inserted in a respective guiding slot of the four guiding slots, such that the frame is slidable vertically relative to the slide board.

10. The server of claim 2, wherein the sidewall is provided with a positioning rack, the positioning rack is located at a rear side of the slide board, the positioning rack is provided with a positioning hole, a rear side of the frame is provided with a positioning pin, the positioning hole is aligned with the positioning pin, when the slide board is slid into the case, the positioning pin is inserted into the positioning hole, the positioning rack is configured to position the frame.

11. The server of claim 1, wherein the slide board is provided with a lock board, the lock board is provided with a buckle slot, the case is provided with a buckle, when the slide board is fully slid into the case, the buckle is inserted into the buckle slot to position the slide board.

12. The server of claim 11, wherein the bracket is provided with a positioning protrusion, when the slide board is slid into the case and the bracket is in the working position, the positioning protrusion is inserted into the buckle slot, the buckle is configured to lock the positioning protrusion, such that the slide board is restricted by the positioning protrusion and is not slidable out of the case, and the bracket is restricted by the buckle and is not rotatable downward to the maintaining position, for simultaneously locking the slide board and the bracket.

13. A server comprising:
a case comprising a sidewall and a front opening, the sidewall comprising a groove rail, the groove rail comprising an inclined section;
a bracket placed in the case and rotatable between a working position and a maintaining position, and the bracket being configured for holding electronic devices;
a chassis comprising a slide board and a frame, wherein the frame is disposed on the slide board and vertically slidable between a lower height and an upper height relative to the slide board, the slide board is disposed on the sidewall and horizontally slidable into or out of the case through the front opening; and
a fan positioned in the frame and configured for cooling the electronic devices, wherein the frame comprises a pin, the pin is slidably disposed in the inclined section, when the slide board is slid into the case, the pin is slid to a lower end of the inclined section, the frame and the fan are moved to the lower height, and the bracket is rotatable to the working position where the electronic devices are between the fan and the opening;
when the bracket is rotated to the maintaining position, the slide board is slidable out of the case, as the slide board is slid out of the case, the pin is slid to an upper end of the inclined section, and the frame and the fan are moved to the upper height, the fan at the upper height is above the bracket in the maintaining position, such that the fan is slidable out of the case for maintenance.

14. The server of claim 13, wherein the groove rail further comprises a lower horizontal section and an upper horizontal section, the lower horizontal section is connected to the lower end of the inclined section, the upper horizontal section is connected to the upper end of the inclined section, the pin is disposed in the groove rail and slidable along the groove rail, when the pin is in the lower horizontal section, the frame and the fan are at the lower height, when the pin is in the upper horizontal section, the frame and the fan are at the upper height, when the slide board slides out of the case, the pin slides from the lower horizontal section through the inclined section into the upper horizontal section, when the pin slides in the inclined section, the frame and the fan move vertically relative to the slide board from the lower height to the upper height.

15. The server of claim 14 further comprises a spring leaf, the spring leaf is disposed on the sidewall, the spring leaf is provided with a sheet, the slide board comprises an edge part and a bump part, the edge part is disposed at the edge of the bump part, the bump part protrudes relative to the edge part toward a side away from the sidewall, the edge part is attached to the sidewall, a hollow space is formed between the bump part and the sidewall, the sheet is located in the hollow space, when the slide board is slid out of the case and the sheet abuts against a tail end of the bump part, the sheet stops the slide board from being detached from the sidewall.

16. The server of claim 15, wherein the tail end of the bump part is provided with a check slot, the check slot is configured to accommodate the sheet, when the slide board is slid out of the case and the sheet is inserted into the check slot, the sheet stops the slide board from being detached from the sidewall.

17. The server of claim 15, wherein the slide board is disposed on an inner surface of the sidewall, one end of the spring leaf is fixed to an outer surface of the sidewall, another end of the spring leaf is provided with a button, the sidewall is provided with a button hole, the button is exposed inside the case through the button hole, the sheet is located on the spring leaf, the sidewall is provided with a slot, when the spring leaf is released, the sheet passes through the slot and extends into the hollow space, when the button is pressed from inside to outside of the case, the spring leaf deforms and the sheet moves out of the slot, such that the sheet leaves the hollow space and the slide board is detachable from the sidewall.

18. The server of claim 14, wherein the slide board is provided with a vertical slot, the vertical slot extends vertically, the pin passes through the vertical slot and is inserted into the groove rail, the pin is slidable in the vertical slot.

19. The server of claim 14, wherein the frame is provided with four guiding slots, each guiding slot extends vertically, the four guiding slots are distributed around the pin, the slide board is provided with four latches, the four latches are fixed on the slide board, each of the four latches is slidably inserted in a respective guiding slot of the four guiding slots, such that the frame is slidable vertically relative to the slide board.

20. The server of claim 14, wherein the sidewall is provided with a positioning rack, the positioning rack is located at a rear side of the slide board, the positioning rack is provided with a positioning hole, a rear side of the frame is provided with a positioning pin, the positioning hole is aligned with the positioning pin, when the slide board is slid into the case, the positioning pin is inserted into the positioning hole, the positioning rack is configured to position the frame.
